(19) United States
(12) Patent Application Publication
(10) Pub. No.: US 2025/0253257 A1
(43) Pub. Date: Aug. 7, 2025

(54) SEMICONDUCTOR MODULE

(71) Applicant: FUJI ELECTRIC CO., LTD., Kanagawa (JP)

(72) Inventors: Rikihiro MARUYAMA, Matsumoto-city (JP); Ryo NOMAGUCHI, Matsumoto-city (JP)

(21) Appl. No.: 19/001,332

(22) Filed: Dec. 24, 2024

(30) Foreign Application Priority Data
Feb. 5, 2024 (JP) 2024-015832

(51) Int. Cl. H01L 23/538; H01L 23/498; H01L 25/07

(52) U.S. Cl. CPC H01L 23/5386; H01L 23/49866; H01L 25/072

(57) ABSTRACT

Provided is a semiconductor module including: a conductive pattern used for internal wiring of the semiconductor module; and one or more wire portions provided in parallel with the conductive pattern, wherein the conductive pattern has: a wiring region having a predetermined width; and a parallel region provided in parallel with the one or more wire portions. The parallel region may include: a pair of coupling regions to which both ends of the one or more wire portions are respectively coupled; and a narrow region provided between the pair of coupling regions and having a narrower width than the wiring region and the pair of coupling regions.

The contents of the following patent application(s) are incorporated herein by reference: NO. 2024-015832 filed in JP on Feb. 5, 2024

### BACKGROUND

### 1. Technical Field

The present invention relates to a semiconductor module.

### 2. Related Art

Patent Document 1, Patent Document 2, Patent Document 3, and Patent Document 4 disclose that a wiring member is provided above a circuit pattern. In addition, Patent Document 5 describes that “slender conductors 24 are overlapped along the extension direction of a ground line 23”.

### PRIOR ART DOCUMENT

### Patent Document

Patent Document 1: International Publication No. 2021-002132
Patent Document 2: Japanese Patent Application Publication No. 2010-251551
Patent Document 3: Japanese Patent Application Publication No. 2001-85611
Patent Document 4: Japanese Patent Application Publication No. H6-338668
Patent Document 5: Japanese Patent Application Publication No. 2014-175613

### BRIEF DESCRIPTION OF THE DRAWINGS

FIG. 1A shows a general configuration of a semiconductor module 100.

FIG. 1B shows one example of a cross section taken along a line a-a′ in FIG. 1A.

FIG. 1C shows one example of an enlarged view of a vicinity of a parallel region 35 of a conductive pattern 30.

FIG. 1D shows one example of an enlarged view of a region A in FIG. 1C.

FIG. 2 shows a modified example of an enlarged view of a vicinity of a parallel region 35 of a conductive pattern 30.

FIG. 3 shows a modified example of an enlarged view of a vicinity of a parallel region 35 of a conductive pattern 30.

FIG. 4 shows a modified example of an enlarged view of a vicinity of a parallel region 35 of a conductive pattern 30.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solving means of the invention.

In the present specification, one side in a direction parallel to a depth direction of a semiconductor substrate included in a semiconductor chip is referred to as an “upper” side, and another side is referred to as a “lower” side. One surface of two main surfaces of a substrate, a layer or another member is referred to as an upper surface, and another surface is referred to as a lower surface. “Upper”, “lower”, “front”, and “back” directions are not limited to a direction of gravity, or a direction of an attachment to a substrate or the like when a semiconductor apparatus is mounted.

In the present specification, technical matters may be described using orthogonal coordinate axes of the X axis, the Y axis, and the Z axis. In the present specification, a surface parallel to an upper surface of the semiconductor chip is referred to as an XY surface, and the depth direction of the semiconductor substrate included in the semiconductor chip is referred to as the Z axis.

In the present specification, a case where a term such as “same” or “equal” is mentioned may include a case where an error due to a variation in manufacturing or the like is included. The error is, for example, within 10%.

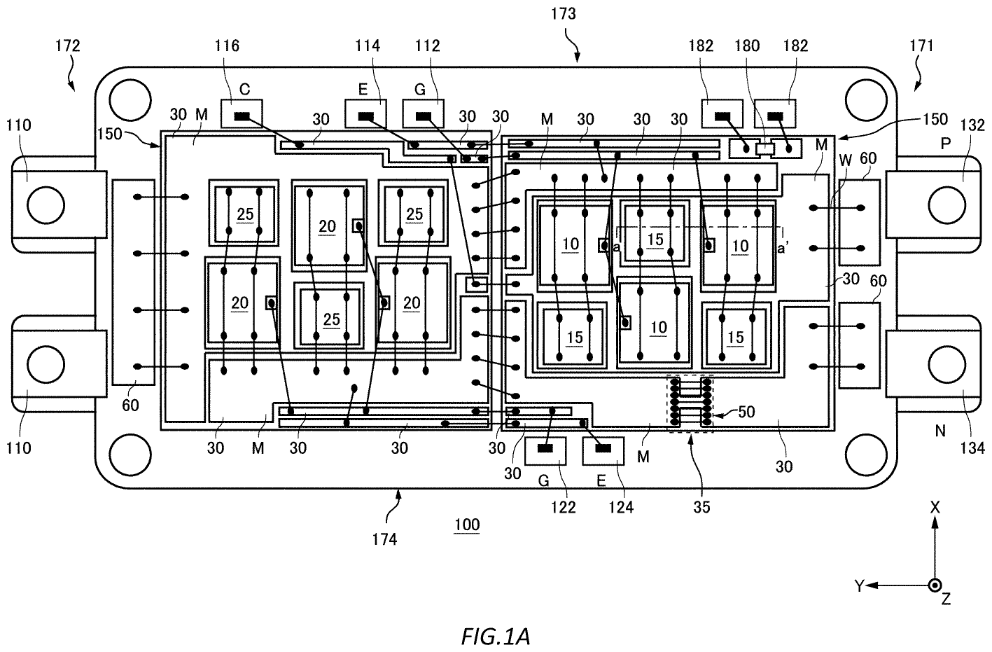

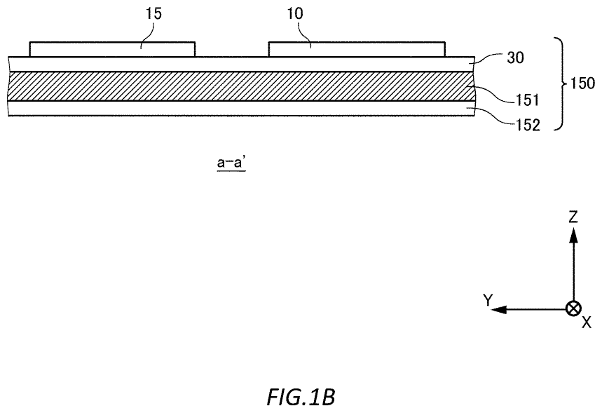

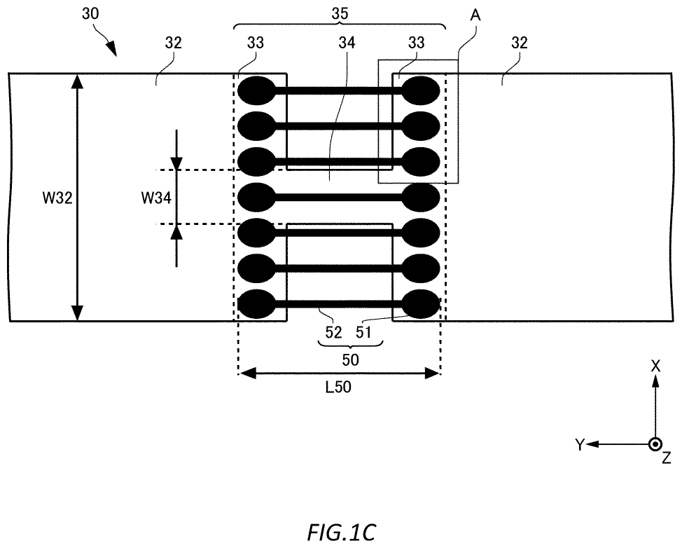

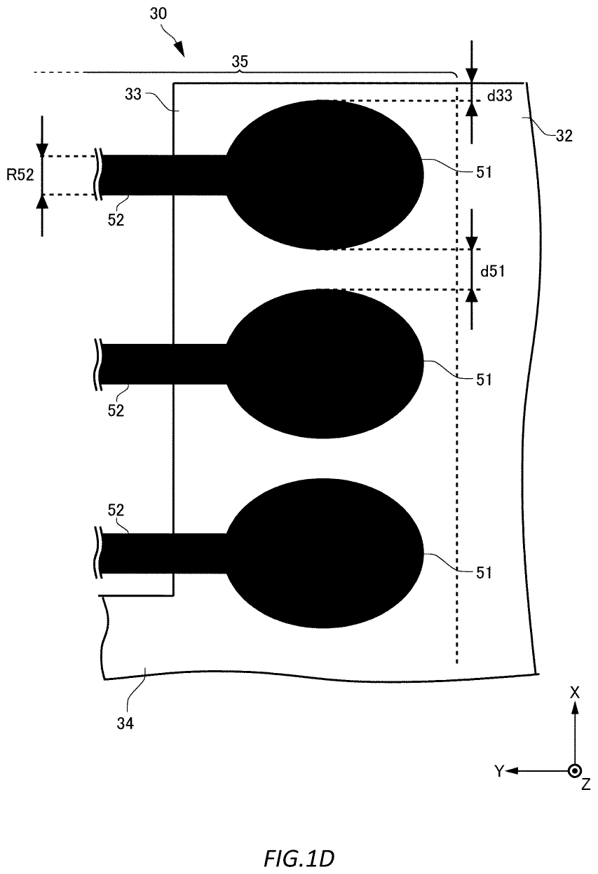

FIG. 1A shows a general configuration of a semiconductor module 100 in the present example. The semiconductor module 100 includes a plurality of laminated substrates 150. Semiconductor devices such as a first switching device 10 and a first diode device 15 are mounted on a laminated substrate 150. The semiconductor module 100 in the present example includes two laminated substrates 150, but the number of laminated substrates 150 is not limited thereto. The semiconductor module 100 in the present example includes, as external terminals, an output terminal 110, a P type terminal 132, an N type terminal 134, a gate external terminal 112, an auxiliary emitter external terminal 114, a gate external terminal 122, an auxiliary emitter external terminal 124, a collector external terminal 116, and a temperature sensing connection terminal 182.

The semiconductor module 100 in the present example has long sides and short sides. As one example, the semiconductor module 100 has a short side 171, a short side 172, a long side 173, and a long side 174. In the semiconductor module 100, the short side 171 and the short side 172 may be oppositely arranged, and the long side 173 and the long side 174 may be oppositely arranged. The short side 171 and the short side 172 in the present example extend in the X axis direction, and are opposed to each other in the Y axis direction. The long side 173 and the long side 174 in the present example extend in the Y axis direction, and are opposed to each other in the X axis direction.

The P type terminal 132 and the N type terminal 134 are provided on a side of the short side 171, which is one of the short sides, of the semiconductor module 100. The P type terminal 132 and the N type terminal 134 are provided on a side extending in the X axis direction on a negative side of the semiconductor module 100 in the Y axis direction. It should be noted that a method for arraying the P type terminal 132 and the N type terminal 134 is not limited thereto. The P type terminal 132 and the N type terminal 134 are each electrically connected to an internal terminal 60. The internal terminal 60 is electrically connected to a conductive pattern 30 through a wire W described later.

The output terminal 110 is an external terminal for electrically connecting to any external load provided outside the semiconductor module 100. The semiconductor module 100 in the present example has two output terminals 110. The output terminals 110 are provided on a side of the short side 172, which is another of the short sides, of the semiconductor module 100. That is, the output terminals 110 in the present example are provided on a side opposite to the side on which the P type terminal 132 and the N type terminal 134 of the semiconductor module 100 are provided. It should be noted that the number of output terminals 110 and a method for arraying them are not limited thereto. The output terminals 110 are electrically connected to an internal terminal 60. The internal terminal 60 is electrically connected to a conductive pattern 30 through a wire W.

The first switching device 10 is provided in an upper arm of the semiconductor module 100. In the present specification, the upper arm refers to a circuit from the P type terminal 132 to the output terminal 110.

The first switching device 10 is a semiconductor device operating as a transistor. The first switching device 10 may be a silicon semiconductor device, or may be a compound semiconductor device. The first switching device 10 may be a SiC-MOS, or may be another switching device such as an insulated gate bipolar transistor (IGBT).

The first switching device 10 has a gate electrode and an emitter electrode as front surface side electrodes, and has a collector electrode as a back surface side electrode. The gate electrode of the first switching device 10 is electrically connected to the gate external terminal 112, and the emitter electrode of the first switching device 10 is electrically connected to the auxiliary emitter external terminal 114. The collector electrode of the first switching device 10 is electrically connected to the collector external terminal 116.

The first diode device 15 is one example of a diode device provided in parallel with the first switching device 10 on the laminated substrate 150. The first diode device 15 serves as a freewheeling diode of the first switching device 10. The first diode device 15 may be a SiC-SBD, or may be a free wheel diode (FWD) formed in a silicon substrate.

A second switching device 20 is provided in a lower arm of the semiconductor module 100, and is provided closer to the short side 172, which is another of the short sides, than the first switching device 10. That is, the second switching device 20 is provided on a positive side of the semiconductor module 100 in the Y axis direction relative to the first switching device 10. In the present specification, the lower arm refers to a circuit from the output terminal 110 to the N type terminal 134.

The second switching device 20 is a semiconductor device operating as a transistor like the first switching device 10, and may be a silicon semiconductor device or may be a compound semiconductor device. The second switching device 20 may be a SiC-MOS, or may be another switching device such as an insulated gate bipolar transistor (IGBT).

The second switching device 20 has a gate electrode and an emitter electrode as front surface side electrodes, and has a collector electrode as a back surface side electrode. The gate electrode of the second switching device 20 is electrically connected to the gate external terminal 122, and the emitter electrode of the second switching device 20 is electrically connected to the auxiliary emitter external terminal 124.

The second diode device 25 is one example of a diode device provided in parallel with the second switching device 20 on the laminated substrate 150. The second diode device 25 serves as a freewheeling diode of the second switching device 20. Like the first diode device 15, the second diode device 25 may be a SiC-SBD, or may be a free wheel diode (FWD) formed in a silicon substrate.

The semiconductor module 100 includes a plurality of conductive patterns 30 used for internal wiring. The conductive patterns 30 are plate members formed of conductive metal. Shapes and arrangement of the conductive patterns 30 may be freely changed depending on a shape of the semiconductor module 100, the number and shapes of switching devices mounted on the semiconductor module 100, and the like. One conductive pattern 30 may be electrically connected to at least one of another conductive pattern 30, a control terminal, or various switching devices via a wire W. The conductive pattern 30 has a parallel region 35 in which one or more wire portions 50 described later are provided in parallel. A structure of the parallel region 35 will be described later in detail.

The parallel region 35 is provided in a main current wiring part M of the semiconductor module 100. The main current wiring part M is a region through which a main current flows during operation of the semiconductor module 100. In the present specification, the main current wiring part M refers to a path from the P type terminal 132 through various switching devices and diode devices to the output terminal 110, and a path from the output terminal 110 through various switching devices and diode devices to the N type terminal 134, of the internal wiring of the semiconductor module 100. Providing the parallel region 35 in the main current wiring part M can reduce a parasitic inductance in the semiconductor module 100.

The parallel region 35 may be provided in at least one of a portion between the first switching device 10 in the upper arm and the P type terminal 132 and/or a portion between the second switching device 20 in the lower arm and the N type terminal 134. The parallel region 35 may be provided in at least one of a portion between the first switching device 10 in the upper arm and the output terminal 110 and/or a portion between the output terminal 110 and the second switching device 20 in the lower arm. The parallel region 35 may be provided in one or both of these regions.

The parallel region 35 may be provided in a portion having a longer wiring path between a portion between the first switching device 10 in the upper arm and the P type terminal 132 and/or a portion between the second switching device 20 in the lower arm and the N type terminal 134. The parallel region 35 may be provided in a portion having a longer wiring path between a portion between the first switching device 10 in the upper arm and the output terminal 110 and/or a portion between the output terminal 110 and the second switching device 20 in the lower arm. Providing the parallel region 35 in a region having a longer wiring path can more effectively reduce the parasitic inductance in the semiconductor module 100.

The gate external terminal 112, the auxiliary emitter external terminal 114, the gate external terminal 122, and the auxiliary emitter external terminal 124 are examples of control terminals for controlling the operation of the semiconductor module 100. The control terminals in the present example are provided on sides orthogonal to the side on which the output terminals 110 are provided. The control terminals in the present example are provided on sides extending in the Y axis direction on a positive side and a negative side of the semiconductor module 100 in the X axis direction. That is, the control terminals in the present example are provided on at least one of a side of the long side 173 or the long side 174 of the semiconductor module 100.

The gate external terminal 112 is electrically connected to the gate electrode of the first switching device 10, and applies a gate voltage. The auxiliary emitter external terminal 114 is electrically connected to the emitter electrode of the first switching device 10, and applies an emitter voltage. In the present example, one gate external terminal 112 and one auxiliary emitter external terminal 114 are provided for a plurality of first switching devices 10, but the numbers of gate external terminals 112 and auxiliary emitter external terminals 114 are not limited thereto. A plurality of gate external terminals 112 and a plurality of auxiliary emitter external terminals 114 may be provided corresponding to a plurality of first switching devices 10, or the number of provided gate external terminals 112 and auxiliary emitter external terminals 114 may correspond to the number of laminated substrates 150 included in the upper arm of the semiconductor module 100. The gate external terminal 112 and the auxiliary emitter external terminal 114 are provided on a side of the long side 173 of the semiconductor module 100.

Similarly, the gate external terminal 122 and the auxiliary emitter external terminal 124 are respectively electrically connected to the gate electrode and the emitter electrode of the second switching device 20, and respectively apply a gate voltage and an emitter voltage. Similarly, a plurality of gate external terminals 122 and a plurality of auxiliary emitter external terminals 124 may be provided corresponding to a plurality of second switching devices 20, or the number of provided gate external terminals 122 and auxiliary emitter external terminals 124 may correspond to the number of laminated substrates 150 included in the lower arm of the semiconductor module 100. The gate external terminal 122 and the auxiliary emitter external terminal 124 are provided on a side of the long side 174 of the semiconductor module 100.

The collector external terminal 116 is electrically connected to the collector electrode of the first switching device 10, and outputs a collector voltage to the outside of the semiconductor module 100. Measuring the collector voltage outside the semiconductor module 100 via the collector external terminal 116 can determine whether a collector-emitter voltage of the first switching device 10 in the upper arm does not have an abnormal value, and can, when it has an abnormal value, stop the operation of the semiconductor module 100 to prevent destructive failure or abnormal operation. It should be noted that measuring a collector voltage of the second switching device 20 outside the semiconductor module 100 via the auxiliary emitter external terminal 114 can determine whether a collector-emitter voltage of the second switching device 20 in the lower arm does not have an abnormal value, and can, when it has an abnormal value, stop the operation of the semiconductor module 100 to prevent destructive failure or abnormal operation.

The temperature sensing connection terminal 182 is electrically connected to a temperature sensing portion 180. The temperature sensing portion 180 may be a thermistor which is embedded inside a housing of the semiconductor module 100 and detects temperature inside the housing.

FIG. 1B shows one example of a cross section taken along a line a-a′ in FIG. 1A. The laminated substrate 150 includes a conductive pattern 30, an insulating plate 151, and a metal plate 152.

The laminated substrate 150 may be a direct copper bonding (DCB) substrate or an active metal brazing (AMB) substrate. The semiconductor module 100 in the present example includes two laminated substrates 150 arrayed in the Y axis direction, but the number of laminated substrates 150 and a method for arraying them are not limited thereto.

The insulating plate 151 is formed of a flat insulating material having any thickness in the Z axis direction and having an upper surface and a lower surface. A main surface of the laminated substrate 150 may be an upper surface of the insulating plate 151. The insulating plate 151 may be formed of a ceramic material such as aluminum oxide (Al₂O₃), aluminum nitride (AlN), or silicon nitride (Si₃N₄). The insulating plate 151 may be formed of a resin material such as epoxy, an epoxy resin material using a ceramic material as filler, or the like.

The conductive pattern 30 is a conductive member having any thickness in the Z axis direction and provided on the upper surface of the insulating plate 151. The metal plate 152 is a conductive member having any thickness in the Z axis direction and provided on a lower surface of the insulating plate 151. The conductive pattern 30 and the metal plate 152 may be each formed of a plate containing a metal material such as copper and a copper alloy. The conductive pattern 30 and the metal plate 152 may be fixed to the insulating plate 151 by using solder, brazing filler metal, and the like. The metal plate 152 may be formed of a thermally conductive material such as copper or aluminum, and serve as a heat sink.

FIG. 1C shows one example of an enlarged view of a vicinity of a parallel region 35 of a conductive pattern 30. A semiconductor module 100 in the present example includes the conductive pattern 30 used for internal wiring of the semiconductor module 100, and one or more wire portions 50 provided in parallel with the conductive pattern 30. The conductive pattern 30 and the one or more wire portions 50 are both configured to allow a main current to flow therethrough during operation of the semiconductor module 100.

The conductive pattern 30 has a wiring region 32 with a predetermined width W32. The width W32 of the wiring region 32 may be changed depending on arrangement of the conductive pattern 30 in the semiconductor module 100, or the like. The width W32 may be 2 mm or larger, and may be 15 mm or smaller. Increasing the width W32 can increase magnitude of a current flowing through the wiring region 32 of the conductive pattern 30.

The conductive pattern 30 has the parallel region 35 provided in parallel with the one or more wire portions 50. In the example shown in FIG. 1C, the parallel region 35 has seven wire portions 50, but the number of wire portions 50 is not limited thereto. In the parallel region 35, wire portions 50 may be continuously provided from one end portion to another end portion in a width direction of the conductive pattern 30, to the extent that bonding portions 51 described later do not contact each other.

Material of the one or more wire portions 50 includes at least one of aluminum or copper. The material of the one or more wire portions 50 may be changed depending on a current characteristic or a temperature characteristic required for the semiconductor module 100. In one example, the material of the one or more wire portions 50 is copper. Forming the wire portions 50 of copper can improve heat exhaust efficiency of the wire portions 50.

The one or more wire portions 50 include a plurality of bonding wires 52, and a plurality of bonding portions 51 provided in end portions of the plurality of bonding wires 52 and connected to the plurality of bonding wires 52. The bonding wires 52 are wires formed of a conductive material such as aluminum or copper. The bonding portions 51 may be formed of the same material as that of the bonding wires 52. A bonding portion 51 couples a bonding wire 52 to a coupling region 33.

The material of the wire portions 50 provided in the parallel region 35 may be the same as or different from material of a wire W connecting a semiconductor device such as a first switching device 10 to the conductive pattern 30 in the semiconductor module 100. In the present example, the material of the wire portions 50 provided in the parallel region 35 is the same as the material of the wire W connecting the semiconductor device to the conductive pattern 30. This can reduce an additional process for forming the wire portions 50.

In the parallel region 35, a pair of coupling regions 33 are regions to which both ends of the one or more wire portions 50 are respectively coupled. The pair of coupling regions 33 are regions, to which the bonding portions 51 of the wire portions 50 are coupled, of the wiring region 32. A width of the pair of coupling regions 33 is the same as the width W32 of the wiring region 32, but is not limited thereto. A width of the coupling regions 33 may be changed to be smaller than the width W32 of the wiring region 32, depending on a position in the semiconductor module 100 where the parallel region 35 is arranged, or the like.

A narrow region 34 is a region provided between the pair of coupling regions 33 in the parallel region 35 and having a narrower width than the wiring region 32 and the pair of coupling regions 33. The narrow region 34 in the present example has a predetermined width W34 in the width direction of the conductive pattern 30. In one example, in the width direction of the conductive pattern 30, the width W34 of the narrow region 34 is 15% or more and 50% or less of the width W32 of the wiring region 32. The width W34 may be 1 mm or larger, and may be 7.5 mm or smaller.

The wiring region 32, the coupling regions 33, and the narrow region 34 in the present example are constructed of the same material, and have the same thickness in the Z axis direction. In this case, electrical resistance in the narrow region 34 is higher than electrical resistance in the wiring region 32 and the coupling regions 33, so that during the operation of the semiconductor module 100, a current flowing through the conductive pattern 30 decreases and a current flowing through the one or more wire portions 50 increases. In one example, the current flowing through the one or more wire portions 50 is 25% or more and 50% or less of a current flowing through the parallel region 35.

In the semiconductor module 100 in the present example, in the parallel region 35, the main current flows through both the conductive pattern 30 and the one or more wire portions 50. This can reduce a parasitic inductance in the semiconductor module 100 compared to a case where most of the main current flows through the conductive pattern 30. The parasitic inductance can be reduced by making an amount of a current flowing through the narrow region 34 equal to an amount of the current flowing through the one or more wire portions 50.

In an extending direction of the conductive pattern 30, a length L50 of a wire portion 50 is larger than a length of the narrow region 34. The length L50 of the wire portion 50 may be a length from an edge of one bonding portion 51 to an edge of another bonding portion 51. The length L50 of the wire portion 50 may be smaller than 350% of the length of the narrow region 34. In one example, in the extending direction of the conductive pattern 30, the length L50 of the one or more wire portions 50 is 3 mm or larger and 8 mm or smaller. Setting the length L50 of the one or more wire portions 50 to 5 mm or smaller can reduce heat generation during the operation of the semiconductor module 100.

FIG. 1D is an enlarged view of a region A in FIG. 1C. With reference to FIG. 1D, a configuration of the one or more wire portions 50 will be further described.

The plurality of bonding portions 51 are provided at a predetermined interval d51 from one end to another end of the wiring region 32 in a width direction of the wiring region 32. Adjusting the interval d51 at which the plurality of bonding portions 51 are provided can continuously arrange a plurality of wire portions 50 over an entire surface in the width direction of the conductive pattern 30 while preventing interference from being caused between the bonding portions 51.

The interval d51 at which the plurality of bonding portions 51 are provided may be changed depending on a diameter R52 of the bonding wires 52. In the example shown in FIG. 1D, the predetermined interval d51 between the plurality of bonding portions 51 is smaller than the diameter R52 of each bonding wire 52 of the plurality of bonding wires 52. This can increase the number of bonding wires 52 provided in parallel while avoiding interference between adjacent bonding portions 51.

The interval d51 at which the plurality of bonding portions 51 are provided may be 30% or more and 70% or less of the diameter R52 of the bonding wires 52. The interval d51 may be 0.1 mm or larger, and may be 0.4 mm or smaller.

In the width direction of the wiring region 32, a distance d33 between a bonding portion 51 arranged closest to an end portion of the wiring region 32 among the plurality of bonding portions 51 and the end portion of the wiring region 32 may be changed depending on the diameter R52 of the bonding wires 52. In the example shown in FIG. 1D, the distance d33 is smaller than the diameter R52 of each bonding wire 52 of the plurality of bonding wires 52. This makes it possible to array the bonding portions 51 up to the end portion of the wiring region 32 and to maximize the number of bonding portions 51 which can be arrayed.

The diameter R52 of each bonding wire 52 of the plurality of bonding wires 52 may be changed depending on magnitude of inductance required for the semiconductor module 100. The diameter R52 of each bonding wire 52 of the plurality of bonding wires 52 is 300 μm or larger and 600 μm or smaller. The diameter R52 may be 300 μm, may be 400 μm, or may be 500 μm.

The diameter R52 of the bonding wires 52 may be the same as or different from a diameter of the wire W connecting the first switching device 10 or the like to the conductive pattern 30. In one example, the diameter R52 of the bonding wires 52 is greater than the diameter of the wire W connecting the first switching device 10 or the like to the conductive pattern 30. This can reduce inductance in the bonding wire 52 and reduce inductance in an entirety of the semiconductor module 100.

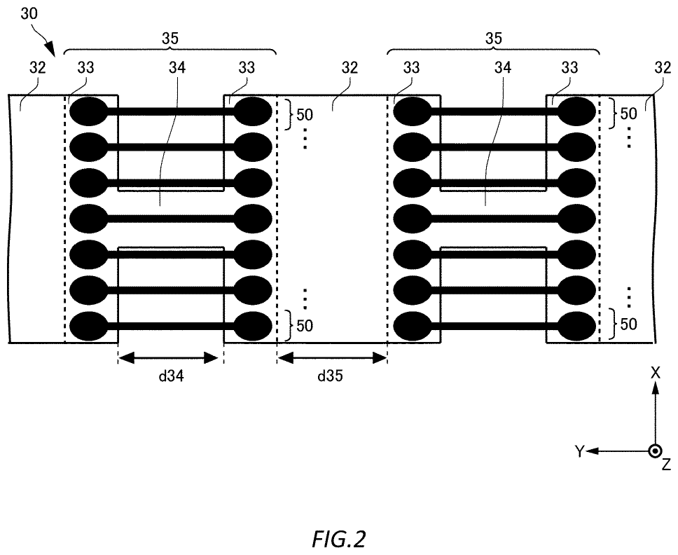

FIG. 2 shows a modified example of an enlarged view of a vicinity of a parallel region 35 of a conductive pattern 30. With reference to FIG. 2, differences from FIG. 1C will be described. The conductive pattern 30 in the present example has a plurality of parallel regions 35.

The plurality of parallel regions 35 are arranged in series in the conductive pattern 30. The conductive pattern 30 may have two parallel regions 35, or may have three or more parallel regions 35. The conductive pattern 30 having the plurality of parallel regions 35 can further reduce inductance in a semiconductor module 100.

The plurality of parallel regions 35 are spaced apart by a predetermined interval d35. The predetermined interval d35 may be larger than a width d34 of a narrow region 34 in an extending direction of the conductive pattern 30. In one example, the interval d35 is 1 mm or larger and 20 mm or smaller. Adjusting the interval d35 at which the plurality of parallel regions 35 are provided can reduce heat generation in the semiconductor module 100.

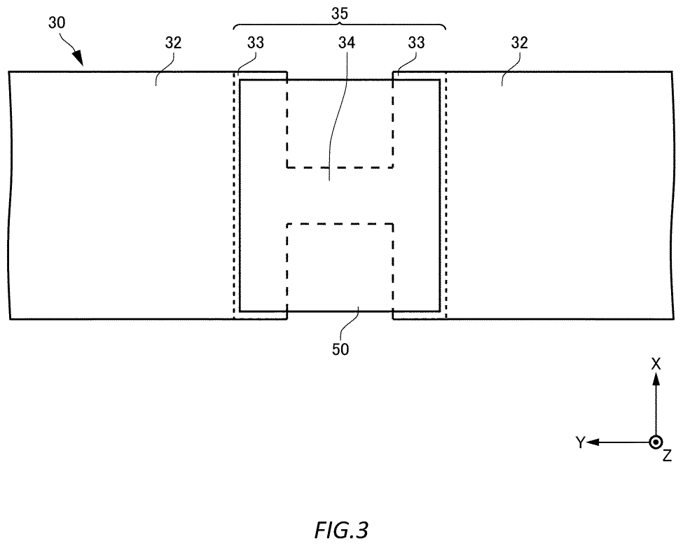

FIG. 3 shows a modified example of an enlarged view of a vicinity of a parallel region 35 of a conductive pattern 30. With reference to FIG. 3, differences from FIG. 1C will be described.

In the example shown in FIG. 3, one or more wire portions 50 include a ribbon wire. The ribbon wire may be an aluminum ribbon, or may be a copper ribbon. The wire portions 50 being ribbon wires can adjust resistance in the wire portions 50 relative to resistance in an entirety of the parallel region 35 by changing a thickness of the wire portions 50 and adjust a value of a parasitic inductance in an entirety of a semiconductor module 100.

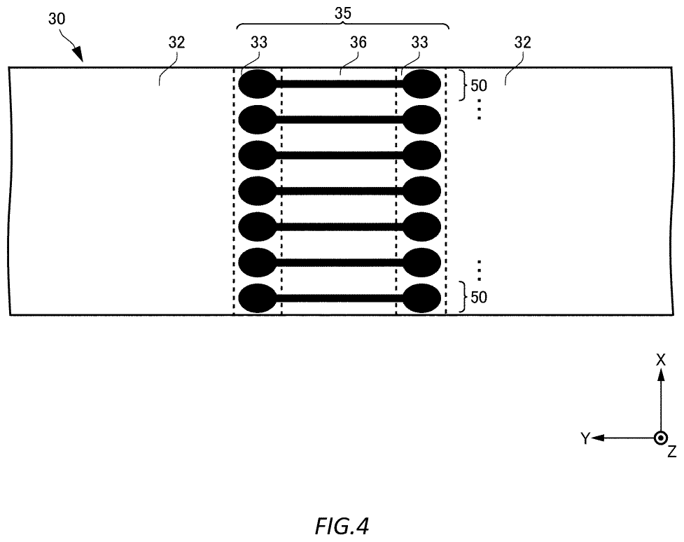

FIG. 4 shows a modified example of an enlarged view of a vicinity of a parallel region 35 of a conductive pattern 30. With reference to FIG. 4, differences from FIG. 1C will be described.

In the example shown in FIG. 4, no narrow region 34 is provided between a pair of coupling regions 33. In the example shown in FIG. 4, an intermediate region 36 is provided between the pair of coupling regions 33, where the intermediate region 36 has a resistance value different from that of the coupling regions 33.

The resistance value of the intermediate region 36 is greater than the resistance value of the coupling regions 33. In one example, in the Z axis direction, a thickness of the intermediate region 36 is 15% or more and 50% or less of a thickness of the coupling regions 33. The intermediate region 36 may have a resistance value greater than the resistance value of the coupling regions 33 as a result of the intermediate region 36 being formed of material different from that of the coupling regions 33, and may have a resistance value greater than the resistance value of the coupling regions 33 due to implantation processing performed on the intermediate region 36. Adjusting the resistance value of the intermediate region 36 can adjust resistance in one or more wire portions 50 relative to resistance in an entirety of the parallel region 35. The resistance in the one or more wire portions 50 may be 100% or more and 300% or less of resistance in the parallel region 35. In this manner, even if no narrow region 34 is provided, it is possible to adjust the resistance in the one or more wire portions 50 relative to the resistance in the entirety of the parallel region 35, and to reduce a parasitic inductance in an entirety of a semiconductor module 100.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: first switching device, 15: first diode device, 20: second switching device, 25: second diode device, 30: conductive pattern, 32: wiring region, 33: coupling region, 34: narrow region, 35: parallel region, 36: intermediate region, 50: wire portion, 51: bonding portion, 52: bonding wire, 60: internal terminal, 100: semiconductor module, 110: output terminal, 112: gate external terminal, 114: auxiliary emitter external terminal, 116: collector external terminal, 122: gate external terminal, 124: auxiliary emitter external terminal, 132: P type terminal, 134: N type terminal, 150: laminated substrate, 151: insulating plate, 152: metal plate, 171: short side, 172: short side, 173: long side, 174: long side, 180: temperature sensing portion, and 182: temperature sensing connection terminal.

What is claimed is:

1. A semiconductor module comprising:
a conductive pattern used for internal wiring of the semiconductor module; and
one or more wire portions provided in parallel with the conductive pattern, wherein
the conductive pattern has:
a wiring region having a predetermined width; and
a parallel region provided in parallel with the one or more wire portions, and
the parallel region includes:
a pair of coupling regions to which both ends of the one or more wire portions are respectively coupled; and
a narrow region provided between the pair of coupling regions and having a narrower width than the wiring region and the pair of coupling regions.

2. The semiconductor module according to claim 1, wherein
in a width direction of the conductive pattern, a width of the narrow region is 15% or more and 50% or less of a width of the wiring region.

3. The semiconductor module according to claim 1, wherein
a current flowing through the one or more wire portions is 25% or more and 50% or less of a current flowing through the parallel region.

4. The semiconductor module according to claim 1, wherein
the conductive pattern has a plurality of parallel regions including the parallel region.

5. The semiconductor module according to claim 4, wherein
the plurality of parallel regions are arranged in series in the conductive pattern.

6. The semiconductor module according to claim 1, wherein
in an extending direction of the conductive pattern, a length of the one or more wire portions is 3 mm or larger and 8 mm or smaller.

7. The semiconductor module according to claim 1, wherein
the one or more wire portions has:
a plurality of bonding wires; and
a plurality of bonding portions provided in end portions of the plurality of bonding wires and connected to the plurality of bonding wires, and
the plurality of bonding portions are provided at a predetermined interval from one end to another end of the wiring region in a width direction of the wiring region.

8. The semiconductor module according to claim 2, wherein
the one or more wire portions has:
a plurality of bonding wires; and
a plurality of bonding portions provided in end portions of the plurality of bonding wires and connected to the plurality of bonding wires, and
the plurality of bonding portions are provided at a predetermined interval from one end to another end of the wiring region in a width direction of the wiring region.

9. The semiconductor module according to claim 3, wherein
the one or more wire portions has:
a plurality of bonding wires; and
a plurality of bonding portions provided in end portions of the plurality of bonding wires and connected to the plurality of bonding wires, and
the plurality of bonding portions are provided at a predetermined interval from one end to another end of the wiring region in a width direction of the wiring region.

10. The semiconductor module according to claim 4, wherein
the one or more wire portions has:
a plurality of bonding wires; and
a plurality of bonding portions provided in end portions of the plurality of bonding wires and connected to the plurality of bonding wires, and
the plurality of bonding portions are provided at a predetermined interval from one end to another end of the wiring region in a width direction of the wiring region.

11. The semiconductor module according to claim 7, wherein
the predetermined interval between the plurality of bonding portions is smaller than a diameter of each bonding wire of the plurality of bonding wires.

12. The semiconductor module according to claim 7, wherein
in the width direction of the wiring region, a distance between a bonding portion arranged closest to an end portion of the wiring region among the plurality of bonding portions and the end portion of the wiring region is smaller than a diameter of each bonding wire of the plurality of bonding wires.

13. The semiconductor module according to claim 7, wherein
a diameter of each bonding wire of the plurality of bonding wires is 300 μm or larger and 600 μm or smaller.

14. The semiconductor module according to claim 1, wherein
material of the one or more wire portions includes at least one of aluminum or copper.

15. The semiconductor module according to claim 1, wherein
the one or more wire portions include a ribbon wire.

16. The semiconductor module according to claim 1, wherein
the semiconductor module has long sides and short sides, and
the semiconductor module comprises:
a P type terminal and an N type terminal provided on a side of one of the short sides of the semiconductor module;
an output terminal provided on a side of another of the short sides of the semiconductor module;
a first switching device provided in an upper arm; and
a second switching device provided in a lower arm and provided closer to the another of the short sides than the first switching device.

17. The semiconductor module according to claim 16, wherein
the parallel region is provided in a main current wiring part of the semiconductor module.

18. The semiconductor module according to claim 16, wherein
the parallel region is provided in at least one of a portion between the first switching device in the upper arm and the P type terminal and/or a portion between the second switching device in the lower arm and the N type terminal.

19. The semiconductor module according to claim 16, wherein
the parallel region is provided in a portion having a longer wiring path between a portion between the first switching device in the upper arm and the P type terminal and/or a portion between the second switching device in the lower arm and the N type terminal.

20. A semiconductor module comprising:
a conductive pattern used for internal wiring of the semiconductor module; and
one or more wire portions provided in parallel with the conductive pattern, wherein
the conductive pattern has:
a wiring region having a predetermined width; and
a parallel region provided in parallel with the one or more wire portions, and
resistance in the one or more wire portions is 100% or more and 300% or less of resistance in the parallel region.
